(19) United States
(12) Patent Application Publication
(10) Pub. No.: US 2020/0258810 A1
(43) Pub. Date: Aug. 13, 2020

(54) TECHNIQUES FOR COOLING INTEGRATED SYSTEMS

(71) Applicant: Vathys, Inc., Portland, OR (US)

(72) Inventor: Tapabrata Ghosh, Portland, OR (US)

(21) Appl. No.: 16/717,039

(22) Filed: Dec. 17, 2019

Related U.S. Application Data
(63) Continuation-in-part of application No. 16/270,311, filed on Feb. 7, 2019.

(51) Int. Cl. H01L 23/427; H01L 25/065; H01L 21/48

(52) U.S. Cl. CPC H01L 23/427; H01L 21/4889; H01L 25/0655

(57) ABSTRACT

Existing methods of cooling computer chips can be inefficient, when applied to high density computing systems, such as wafer-scale-integrated (WSI) systems and other high-density computing systems. In particular, current methods of cooling integrated circuits can be inefficient when applied to high-density computing systems, as the cooling medium can lose its ability to absorb heat due to heat absorption and aggregation when the cooling medium travels through multiple surfaces and regions of a high-density computing system. In some embodiments, systems and methods of achieving high-density computing, by using bridge dies and standard and/or WSI lithography techniques are disclosed. In other embodiments, systems and methods of cooling high-density computing systems are disclosed. Two-phase immersion cooling that avoids heat aggregation is used.

### CROSS-REFERENCE TO RELATED APPLICATIONS

This application is a continuation-in-part of U.S. patent application Ser. No. 16/270,311, filed on Feb. 7, 2019, entitled “SYSTEMS AND METHODS FOR SCALE OUT INTEGRATION OF CHIPS,” content of which is incorporated herein by reference in its entirety and should be considered a part of this specification.

### BACKGROUND

### Field of the Invention

This invention relates generally to the field of integrated circuits and more particularly to wafer-scale integrated circuits.

### Description of the Related Art

A semiconductor wafer goes through processing stages where multiple layers are deposited, regions etched and portions are removed or added to pattern an integrated circuit onto the semiconductor wafer. Photolithography techniques are used to deposit material, remove material and otherwise create the layers and connections of a chip on a semiconductor wafer. To make mass-production of chips economical, current chip manufacturing techniques create copies of an integrated circuit (IC) on a semiconductor wafer in a grid-like fashion. Each grid contains a die, which is a small block of semiconductor material on which a given functional circuit is fabricated. No manufacturing process is perfect. After fabricating a grid of ICs on a semiconductor wafer, several dies may be defective. The dies are tested and the defective ones are marked. Subsequently, the dies are cut from the semiconductor wafer and packaged, while defective dies are discarded. The dies may be tested again to discard any more defective batches.

Typically, 30% to 50% of the cost of IC manufacturing can be attributed to the cost of testing and packaging the individual chips produced using the above-described common manufacturing practice. At the same time, the current IC fabrication techniques are made economical when multiple dies are fabricated on a single semiconductor wafer and later cut and packaged. Consequently, a long-time objective of the IC manufacturing industry has been to increase yield while reducing the cost associated with testing and packaging individual dies.

Wafer scale integration (WSI) has been proposed as an alternative. WSI fabrication techniques utilize an entire area of a semiconductor wafer to manufacture a super-chip, an integrated circuit whose circuitry extends to all or a large area of a semiconductor wafer, thereby increasing bandwidth, connectivity and other device performance metrics. WSI chips need not go through semiconductor wafer cutting because the entire pattern printed on the wafer is used as a single circuit with one or multiple interconnected circuits implementing functions and subfunctions. WSI devices also promise to substantially reduce the cost of manufacturing ICs because WSI devices need fewer or no wafer cutting and individual die testing. Additionally, the improved hardware performance metrics promised by WSI devices make them good candidates for complex, voluminous and parallel computing tasks, such as those needed in artificial intelligence (AI) applications.

However, most attempts to commercialize and manufacture WSI devices have largely been unsuccessful. It is difficult to fabricate a large design printed on a single semiconductor wafer without any flaws. Additionally, most existing and economically viable lithography systems for IC manufacturing (e.g., 193 nm immersion lithography) are designed with or inherently have limited exposure areas meant for printing copies of small circuit areas on a semiconductor wafer. Optical devices used in lithography equipment have also inherent limitations, which make manufacturing at wafer scale level a challenge.

Besides lithographic and yield challenges hampering the widespread adoption and use of WSI devices, the thermal management of such devices using current technology can be difficult. Forced air, or fluid cooling via channels are methods in use with current computing systems. However, since WSI systems have much higher compute unit density per unit of area, compared to typical modern chips, the cooling air or fluid traveling through various parts of a WSI system can quickly absorb all the heat that the cooling air or fluid has capacity to absorb, and lose its ability to cool additional portions of a WSI chip. This is typically not an issue with non-WSI chips, as the compute density in those devices are much lower than WSI systems and a cooling medium, such as air or fluid, can successfully cool down the chip, before losing its capacity to absorb heat.

Consequently, there is a need for improved cooling systems that can efficiently perform thermal management for WSI devices and other dense computing systems.

### SUMMARY

In one aspect of the invention, an integrated circuit is disclosed. The integrated circuit includes: at least one semiconductor wafer comprising a plurality of dies; functional circuits embedded in the plurality of dies; and at least one bridge die fabricated on two or more plurality of dies and electrically connecting the functional circuits embedded in the two or more plurality of dies such that the plurality of dies provide computing resources in unison.

In one embodiment, the functional circuits comprise one or more of logic circuits and memory circuits.

In another embodiment, the bridge die comprises circuitry configured to additionally provide computing resources.

In some embodiments, the bridge die comprises a semiconductor wafer.

In one embodiment, the semiconductor wafer comprising the bridge die is in face-to-face, face-to-back, back-to-face, or back-to-back in relation to the semiconductor wafer comprising the plurality of dies and relative to die grids printed on the semiconductor wafers.

In some embodiments, the bridge die is connected to the two or more plurality of dies via one or more of: through-silicon-vias (TSV), micro-bumps, solder-bumps, C4 bumps, inductive coupling, capacitive coupling, optical coupling, face to face bonding, bonded metal links, and face-to-face vias.

In one embodiment, the bridge die and the two or more plurality of dies are aligned with an alignment process comprising one or more of moiré fringe alignment processes, key alignment processes, mechanical groove-based alignment processes, pick and place, IR alignment processes, and dual backside alignment processes.

In some embodiments, the bridge die is mechanically connected to the two or more plurality of dies via one or more of direct bonding, anodic bonding, hybrid bonding, glues, epoxies, resins, benzocyclobutene (DVS-BCB) polymers, and thermocompression bonding.

In one embodiment, the plurality of dies comprise a die grid, wherein each die comprises a logic and/or memory circuitry substantially identical to other dies in the die grid.

In an embodiment, a machine learning microprocessor includes the integrated circuit.

In another embodiment, a three-dimensional integrated circuit includes the integrated circuit.

In another aspect of the invention a method of achieving wafer scale integration in an integrated circuit is disclosed. The method includes: providing a semiconductor wafer; fabricating a die grid on the semiconductor wafer, wherein each die comprises a circuit; and connecting two or more circuits of the die grid with one or more bridge dies such that the dies within the die grid provide computing resources in unison.

In one embodiment, the circuit comprises one or more of logic and memory circuits.

In another embodiment, connecting two or more circuits comprises connecting via one or more of through-silicon-vias (TSV), micro-bumps, solder-bumps, C4 bumps, inductive coupling, capacitive coupling, optical coupling, face to face bonding, bonded metal links, and face-to-face vias.

In some embodiments, connecting comprises mechanically connecting via one or more of: direct bonding, anodic bonding, hybrid bonding, glues, epoxies, resins, benzocyclobutene (DVS-BCB) polymers, and thermocompression bonding.

In one embodiment, the method further includes aligning the bridge die and the two and more circuits via one or more of moiré fringe alignment processes, key alignment processes, mechanical groove-based alignment processes, pick and place, IR alignment processes, and dual backside alignment processes.

In some embodiment, the method further includes: providing one or more additional semiconductor wafers, each semiconductor wafer comprising a die grid and wherein the bridge dies each also comprise semiconductor wafer comprising a grid die.

In one aspect a system is disclosed. The system includes: a substrate comprising a plurality of dies arranged in a grid on a face surface of the substrate; one or more bridge dies disposed on the grid and electrically coupling two or more dies in the grid; a tank of dielectric coolant comprising a container of the substrate, wherein the container comprises a vertical direction in which evaporated dielectric coolant travels upward to reach a top surface of the dielectric coolant, and wherein the substrate is immersed in the dielectric coolant, and wherein the face surface of the substrate and the vertical direction of the container form an angle, and wherein the angle deviates from zero degrees in an amount such that the dielectric coolant evaporated from absorbing heat generated from a region of the plurality of the dies travels toward the top surface in the vertical direction avoiding contact with other dies; and a condenser surface disposed above the top surface of the dielectric coolant.

In one embodiment, the system further includes, a plurality of substrates, wherein one or more of the plurality of the substrates comprise one or more of the bridge dies, and wherein one or more of the bridge dies comprise functional circuits.

In another embodiment, the angle comprises an angle between approximately 10 to approximately 90 degrees.

In one embodiment, the dielectric coolant comprises a refringent.

In another embodiment, the refrigerant comprises material from hydrofluorocarbon families.

In some embodiments, the substrates comprise a face surface and a back surface, wherein the face surface comprises the functional circuits and the plurality of the substrates are in face-to-face, face-to-back, back-to-face, or back-to-back orientation in relation to one another.

In another embodiment, the bridge die is connected to the two or more plurality of dies via one or more of: through-silicon-vias (TSV), micro-bumps, solder-bumps, C4 bumps, inductive coupling, capacitive coupling, optical coupling, face to face bonding, bonded metal links, and face-to-face vias.

In one embodiment, the bridge die and the two or more plurality of dies are aligned with an alignment process comprising one or more of moiré fringe alignment processes, key alignment processes, mechanical groove-based alignment processes, pick and place, IR alignment processes, and dual backside alignment processes.

In some embodiments, the bridge die is mechanically connected to the two or more plurality of dies via one or more of direct bonding, anodic bonding, hybrid bonding, glues, epoxies, resins, benzocyclobutene (DVS-BCB) polymers, and thermocompression bonding.

In one embodiment, the grid comprises approximately identical copies of the dies produced from a lithographic technique that prints copies of identical dies on the substrate.

In another embodiment, the system further includes a refrigeration unit coupled with the condenser and configured to cool a temperature of a refrigerant inside the condenser to a temperature below a saturation temperature of the dielectric coolant.

In another aspect, a method is disclosed. The method includes: forming a plurality of dies arranged in a grid on a face surface of a substrate; electrically coupling two or more dies in the grid with one or more bridge dies disposed on the grid; providing a tank of dielectric coolant comprising a container of the substrate, wherein the container comprises a vertical direction in which evaporated dielectric coolant travels upward to reach a top surface of the dielectric coolant; immersing the substrate in the dielectric coolant, wherein the face surface of the substrate and the vertical direction of the container form an angle, and wherein the angle deviates from zero degrees in an amount such that the dielectric coolant evaporated from absorbing heat generated from a region of the plurality of the dies travels toward the top surface in the vertical direction avoiding contact with other dies; and providing a condenser surface disposed above the top surface of the dielectric coolant.

In one embodiment, the method further includes: providing a plurality of substrates, wherein one or more of the plurality of the substrates comprise one or more of the bridge dies, and wherein one or more of the bridge dies comprise functional circuits.

In another embodiment, the angle comprises an angle between approximately 10 to approximately 90 degrees.

In some embodiments, the dielectric coolant comprises a refringent.

In one embodiment, the refrigerant comprises material from hydrofluorocarbon families.

In another embodiment, the substrates comprise a face surface and a back surface, wherein the face surface comprises the functional circuits and the plurality of substrates are in face-to-face, face-to-back, back-to-face, or back-to-back orientation in relation to one another.

In some embodiments, the bridge die is connected to the two or more plurality of dies via one or more of: through-silicon-vias (TSV), micro-bumps, solder-bumps, C4 bumps, inductive coupling, capacitive coupling, optical coupling, face to face bonding, bonded metal links, and face-to-face vias.

In another embodiment, the bridge die and the two or more plurality of dies are aligned with an alignment process comprising one or more of moiré fringe alignment processes, key alignment processes, mechanical groove-based alignment processes, pick and place, IR alignment processes, and dual backside alignment processes.

In some embodiments, the method further includes cooling a refrigerant in circulation in the condenser surface.

In another aspect a system is disclosed. The system includes: a dense computing system, comprising a substrate and a plurality of dies arranged on the substrate; a tank of dielectric coolant comprising a container of the substrate, wherein the container comprises a vertical direction in which evaporated dielectric coolant travels upward to reach a top surface of the dielectric coolant, and wherein the substrate is immersed in the dielectric coolant, and wherein the face surface of the substrate and the vertical direction of the container form an angle, and wherein the angle deviates from zero degrees in an amount such that the dielectric coolant evaporated from absorbing heat generated from a region of the plurality of the dies travels toward the top surface in the vertical direction avoiding contact with other dies; and a condenser surface disposed above the top surface of the dielectric coolant.

In some embodiments, the dense computing system comprises a wafer-scale-integrated computing system or a partially wafer-scale-integrated computing system.

In another embodiment, the angle comprises an angle between approximately 10 to approximately 90 degrees.

In some embodiments, the dielectric coolant comprises a refringent.

In one embodiment, the refrigerant comprises material from hydrofluorocarbon families.

In another embodiment, the face surface comprises functional circuits implementing logic or memory functionality.

In one embodiment, the system, further includes, one or more bridge dies, electrically coupling two or more dies on the substrate; wherein the bridge die is connected to the two or more plurality of dies via one or more of: through-silicon-vias (TSV), micro-bumps, solder-bumps, C4 bumps, inductive coupling, capacitive coupling, optical coupling, face to face bonding, bonded metal links, and face-to-face vias.

In another embodiment, the dense computing system is unpackaged or partially packaged.

In one embodiment, the bridge die is mechanically connected to the two or more plurality of dies via one or more of direct bonding, anodic bonding, hybrid bonding, glues, epoxies, resins, benzocyclobutene (DVS-BCB) polymers, and thermocompression bonding.

In some embodiments, the dies comprise approximately identical copies of the dies produced from a lithographic technique that prints copies of identical dies on the substrate.

In other embodiments, the system further includes a refrigeration unit coupled with the condenser and configured to cool a temperature of a refrigerant inside the condenser to a temperature below a saturation temperature of the dielectric coolant.

In another aspect, a method is disclosed. The method steps include forming a dense computing system on a substrate by forming a plurality of dies on a face surface of the substrate; electrically coupling two or more dies or die regions with one another; providing a tank of dielectric coolant comprising a container of the substrate, wherein the container comprises a vertical direction in which evaporated dielectric coolant travels upward to reach a top surface of the dielectric coolant; immersing the substrate in the dielectric coolant, wherein the face surface of the substrate and the vertical direction of the container form an angle, and wherein the angle deviates from zero degrees in an amount such that the dielectric coolant evaporated from absorbing heat generated from a region of the plurality of the dies travels toward the top surface in the vertical direction avoiding contact with other dies; and providing a condenser surface disposed above the top surface of the dielectric coolant.

In another embodiment, the dense computing system comprises a wafer-scale-integrated computing system or a partially wafer-scale-integrated computing system.

In some embodiments, the angle comprises an angle between approximately 10 to approximately 90 degrees.

In one embodiment, the dielectric coolant comprises a refringent.

In another embodiment, the refrigerant comprises material from hydrofluorocarbon families.

In some embodiments, the face surface comprises implementing logic or memory functionality.

In one embodiment, electrically coupling comprises forming one or more bridge dies, electrically coupling two or more dies on the substrate, wherein the bridge die is connected to the two or more plurality of dies via one or more of: through-silicon-vias (TSV), micro-bumps, solder-bumps, C4 bumps, inductive coupling, capacitive coupling, optical coupling, face to face bonding, bonded metal links, and face-to-face vias.

In another embodiment, the dense computing system is unpackaged or partially packaged.

In some embodiments, the further includes cooling a refrigerant in circulation in the condenser surface.

### BRIEF DESCRIPTION OF THE DRAWINGS

These drawings and the associated description herein are provided to illustrate specific embodiments of the invention and are not intended to be limiting.

FIG. 1 illustrates a WSI chip built using bridge dies according to an embodiment.

FIG. 2 illustrates a WSI chip where an entire semiconductor wafer is utilized as a bridge die according to an embodiment.

FIG. 3 illustrates a WSI chip comprising multiple semiconductor wafers connected using bridge dies according to an embodiment.

FIG. 4 illustrates an example two-phase cooling system deployed to provide thermal management to one or more dense computing systems.

FIG. 5 illustrates an alternative arrangement of the two-phase cooling system, where the dense computing systems are arranged horizontally in a tank of dielectric coolant.

FIG. 6A illustrates a dense computing system placed vertically in a tank of dielectric coolant.

FIG. 6B illustrates a dense computing system in the horizontal arrangement, where the longer dimension of the dense computing system is perpendicular or nearly perpendicular to the travel direction of evaporated droplets.

FIG. 7 illustrates a dense computing system arranged with a slight angle, relative to the travel direction of the evaporated droplets.

FIG. 8 illustrates a flowchart of a method for cooling a dense computing system, according to an embodiment.

### DETAILED DESCRIPTION

The following detailed description of certain embodiments presents various descriptions of specific embodiments of the invention. However, the invention can be embodied in a multitude of different ways as defined and covered by the claims. In this description, reference is made to the drawings where like reference numerals may indicate identical or functionally similar elements.

Unless defined otherwise, all terms used herein have the same meaning as are commonly understood by one of skill in the art to which this invention belongs. All patents, patent applications and publications referred to throughout the disclosure herein are incorporated by reference in their entirety. In the event that there is a plurality of definitions for a term herein, those in this section prevail. When the terms “one”, “a” or “an” are used in the disclosure, they mean “at least one” or “one or more”, unless otherwise indicated.

### Definitions

“die” is a small block of semiconductor material on which a given functional circuit is fabricated.

“bridge die,” according to the described embodiments is a chip, die, substrate or connection means fabricated between one or more die regions or one or more semiconductor wafers in order to provide connections between those die regions and/or the semiconductor wafers. Connections can be used for communication, power delivery or other functions to integrate the functionality of the die regions connected via bridge dies.

“Scale out integration,” according to the described embodiments, is a method of achieving wafer-scale integration by using one or more bridge dies (e.g., chips, dies, substrates) fabricated to overlap with one or more die areas within a semiconductor wafer to create connections between those die areas.

Most challenges of wafer-scale integration are due to inherent limitations in lithographic techniques and the inability of fabrication techniques to create reliable connections (at wafer-scale dimensions) between dies printed on a semiconductor wafer. Additionally, current and standard lithographic technology are mostly geared for printing multiple copies of a chip on a semiconductor wafer and not for printing wafer-scale chips.

For example, in one respect, fabricating a monolithic computing system on a semiconductor wafer area greater than approximately 858 millimeter-squares (mm2) can be considered fabricating a WSI system. This has been an aspirational goal in the context of WSI systems for decades, especially in the context of computing systems, designed to handle highly parallel computing workloads, such as high-performance computing (HPC) and artificial intelligence. However, lithographic systems, even more modern lithographic systems such as 193 nanometer (nm) immersion lithography, can achieve a somewhat limited exposure area, due to optical challenges present even in modern lithographic equipment. Limited exposure area and other optical challenges of available lithographic and fabrication techniques, can make fabricating large-scale, or wafer-scale single circuits difficult to achieve.

In one embodiment, a scale out integration is proposed where one or more bridge dies can be used to create connections between dies on a semiconductor wafer, thereby achieving wafer-scale integration. The dies can contain identical, similar or different circuits manufactured and patterned using standard fabrication equipment or specialized WSI fabrication equipment.

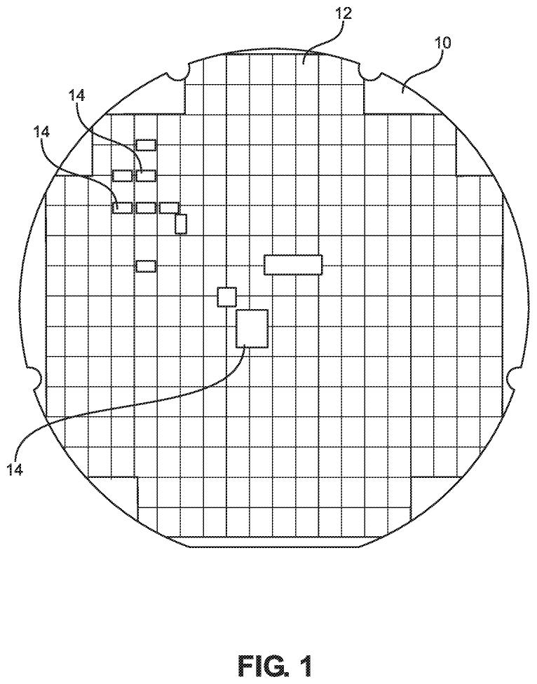

FIG. 1 illustrates a semiconductor wafer 10 and a die grid 12 printed on the semiconductor wafer 10. Die grid 12 can contain identical or diverse ICs implementing one or more memory and/or logical functions as may be used in computing systems. These functions can be implemented with circuits, such as, adder circuits, memory circuits, inverters, multipliers, shifters, “AND,” “OR,” “XOR,” “NOR” circuits and others. In one embodiment, one or more bridge dies 14 can be fabricated on top of the die grid 12 to create connections between dies of the grid 12. Bridge dies 14 can vary in shape, size and numbers depending on the embodiment. In some embodiments, the bridge dies 14 can be used to bypass or rewire defective dies in the die grid 12 and/or create connections between dies on the die grid 12 to allow for integrated circuits with greater computational abilities and bandwidth. For example, bridge dies 14 can be used to connect several memory modules creating a large, high bandwidth and fast memory architecture on the semiconductor wafer 10.

While FIG. 1 illustrates few bridge dies 14 for the purposes of brevity, more bridge dies 14 may be implemented depending on the embodiment. For example, in some embodiments, all die areas may be connected together with the use of bridge dies at all or substantially most abutment points between the dies of the die grid 12. Yet, in other embodiments, not all wafer areas are connected using bridge dies 14 and only some or portions of the die grid 12 may be interconnected using bridge dies 14 to create functional circuits. Depending on the lithography technology used, bridge dies can connect dies or die regions greater in size than the single reticle size allows. For example, in some modern lithographic technologies, available reticle sizes can make a region of maximum area of approximately 858 mm² on a semiconductor wafer 10 available for patterning and manufacturing of chips per exposure. consequently, bridge dies can be used to cover and connect any die area larger than or equal to 858 mm2. Additionally, when standard lithography techniques are used, bridge dies 14 can increase feature resolution in an area of the die grid 12 where they are deployed.

Some prior efforts to achieve wafer-scale integration have failed due to unavailability or impracticality of fabrication and lithography equipment capable of printing single-design, large circuit areas on a semiconductor wafer. Although, the described embodiments can be effectively used in a single or large-scale chip design, they allow a standard printed semiconductor wafer to achieve wafer-scale integration by externally connecting the multiple dies of the semiconductor wafer and the circuits embedded in them. Therefore, the described embodiments do not require prohibitively expensive or impractical fabrication equipment and high performance, resource-efficient computing systems can be built with the semiconductor wafers retrofitted with the described embodiments using standard lithography techniques.

Additionally, a variety of semiconductor wafers and substrates can be used to implement the semiconductor wafer 10. Examples include a 100 mm circular wafer, 300 mm circular wafer, square wafers, clover-shaped semiconductor wafers and semiconductor wafers of regular or irregular shapes.

A number of communication and power delivery techniques may be used between the bridge dies 14 and die areas within the die grid 12. Examples include, one or some combination of: through-silicon-vias (TSV), micro-bumps, solder-bumps, C4 bumps, inductive coupling, capacitive coupling, optical coupling, face to face bonding, bonded metal links, and face-to-face vias. The communication and power delivery techniques may be the same or can vary between bridge dies 14 and the grid 12 in various wafer regions.

Depending on the embodiment, the bridge dies 14 may be passive (no power required), active, or some combination of the two. Both or only one of active and passive bridge dies may be used on the die grid 12 depending on the circuit implemented by the embodiment of FIG. 1. In some embodiments, the bridge dies 14 may be active and also include circuitry to perform computation or they may be passive and provide electrical connection without performing computational tasks.

In other embodiments, more than one layer of bridge die and/or semiconductor wafers can be used to create a three-dimensional integrated circuit configuration.

Various alignment processes can be used to properly align bridge dies 14 with the dies in the die grid 12. Example alignment processes can include, one or more of moiré fringe alignment processes, key alignment processes, mechanical groove-based alignment processes, pick and place, infrared (IR) alignment processes, and dual backside alignment processes.

In some embodiments, one or more mechanical connections between bridge dies 14 and wafer die areas on die grid 12 may be used to secure the bridge dies 14 to the die grid 12. Example mechanical connections include, direct bonding, anodic bonding, hybrid bonding, glues, epoxies, resins, benzocyclobutene (DVS-BCB) polymers, and thermocompression bonding. In other embodiments, mechanical connections between bridge dies and wafer die areas can be omitted.

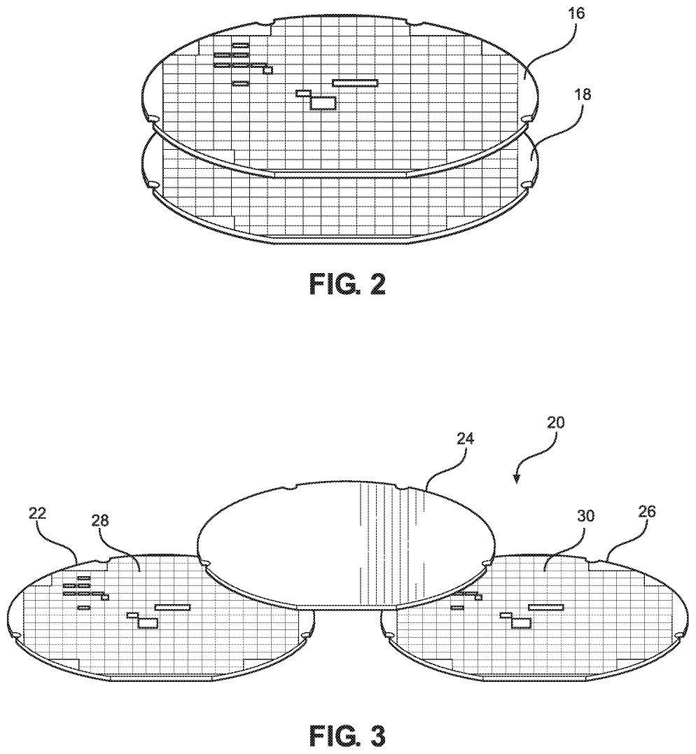

Bridge dies 14 can be as large or as small as needed to implement the circuitry desired. For example, an entire semiconductor wafer can be used as bridge die. FIG. 2 illustrates a semiconductor wafer 18 and a bridge die 16 where an entire semiconductor wafer is used as bridge die 16. One, some, or all dies within the bridge die 16 can be used to provide connections, power and/or computational circuitry to the chips within the semiconductor die 18. Additionally, the bridge die 16 can be perfectly, or near perfectly aligned with the semiconductor wafer 18 or have a vertical and/or horizontal offset with semiconductor wafer 18 in order to line up and connect desired chips between the bridge die 16 and the semiconductor wafer 18.

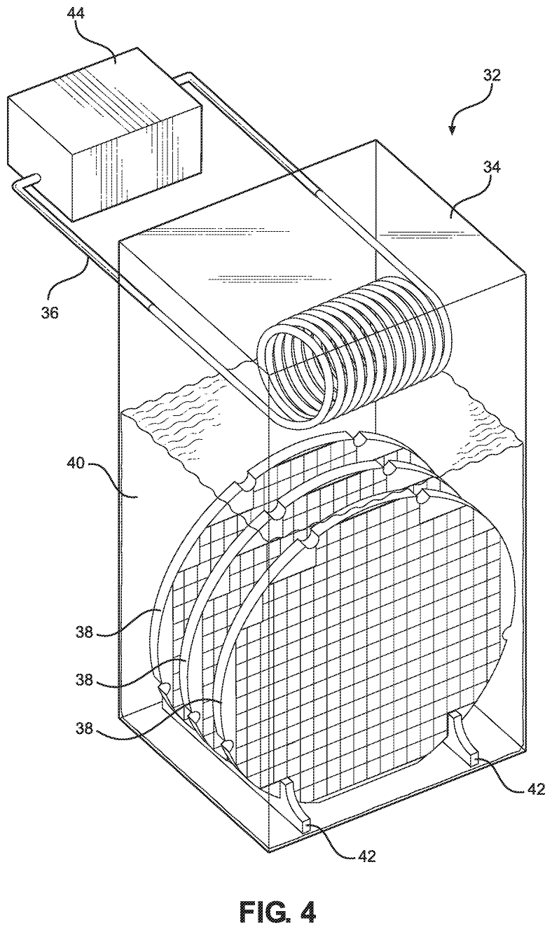

FIG. 3 illustrates an embodiment of a wafer-scale-integrated IC 20 where bridge dies are used to connect multiple semiconductor wafers. The IC 20 includes semiconductor wafer 22 connected with bridge die 24 to another semiconductor wafer 26. Semiconductor wafer 22 can include a die grid 28 where computational circuits are implemented on a substrate. Semiconductor wafer 26 can include a die grid 30 where additional computational circuits are implemented on a substrate. Bridge die 24 can be connected to the semiconductor wafers 22 and 26 in a face-down configuration with respect to wafers 22 and 26. Bridge die 24 can also include a die grid, which is not visible in the view shown.

While only one bridge die 24 (as a whole wafer bridge die) and two semiconductor wafers 22 and 26 are shown in FIG. 3, a plurality of semiconductor wafers and more bridge dies can be used to scale out the IC 20 to larger systems, enabling massive computing systems with large bandwidth and computational circuitry.

While the bridge die 24 is shown in a face-to-face orientation relative to the semiconductor wafers 22 and 26 (and relative to where the die grids 28, 30 and die grid of bridge die 24 are printed), other orientations are also possible. These can include for example, face-to-back, back-to-back and or a combination of them.

Applications

The proposed embodiments allow for the creation of large monolithic computing systems with large high interconnect and memory bandwidth. Such a system is particularly useful for highly parallel computing workloads, such as, but not limited to: machine learning, deep learning, supercomputing, high performance computing (HPC), weather simulations, nuclear simulations, parallel simulations, graph algorithms, and others.

Systems and Methods for Cooling Computer Hardware

In one respect, WSI systems, including the described embodiments and other WSI systems utilizing highly integrated systems, for example having multilayered ICs or other similar systems can be considered dense computing systems packing massive computing power per unit of area. During their operations, dense computing systems can generate more heat per unit of area/volume compared to less dense computing systems. Various methods and devices can be used to provide cooling and thermal management for dense computing systems. Existing methods include forced air or liquid cooling, where air or fluid is forced over an IC system area or volume, removing heat from the IC system. A heat exchange mechanism, such as a cooling compressor or chiller can remove the heat from the forced air or fluid. One challenge forced air or fluid cooling techniques in this manner faces is heat aggregation. By the time, the forced air or fluid travels from one end of an IC system (e.g., a silicon wafer) to another end, the forced air or fluid has absorb heat by a large amount and may be unable to remove heat from the nearby areas of the IC system, thereby making the application of forced air/liquid cooling technique to dense computing systems inefficient.

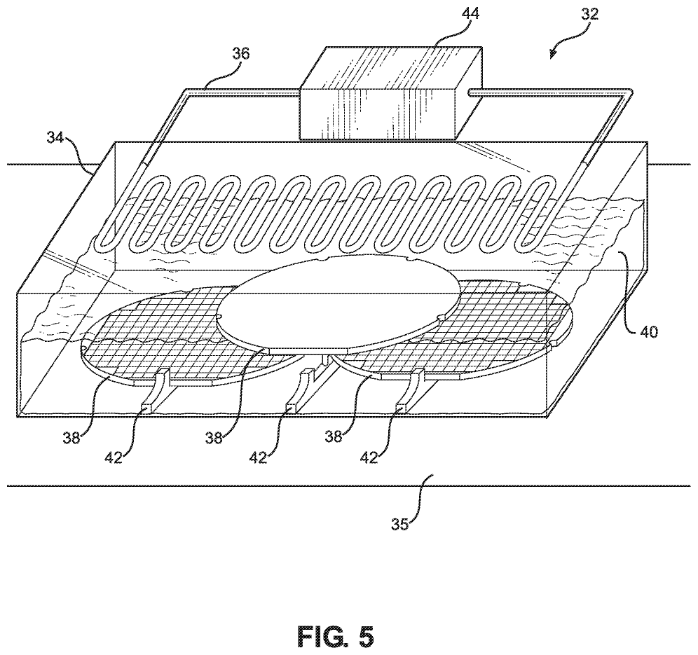

Two-phase immersion cooling techniques can be applied to dense computing systems to provide efficient thermal management. FIG. 4 illustrates an example two-phase cooling system 32 deployed to provide thermal management to one or more dense computing systems 38. Dense computing systems 38 can be any computing systems, such as standard wafer-scale-integrated (WSI) systems, WSI systems utilizing die bridges as described above, three-dimensional (3D) ICs, multilayered ICs, or any other computing system. The cooling system 32 can include a tank 34, a dielectric coolant 40, and a condenser 36. One or more dense computing systems 38 can be secured in the tank 34 via stands 42, or a rack and/or rail system or other means of mechanical support depending on the shape, dimensions and numbers of the dense computing systems 38. The dielectric coolant 40 can be a dielectric liquid with a low evaporation point (e.g., around 50° C.). Example dielectric coolants can include hydrofluorocarbon families and other refrigerant families. External connections to and from the dense computing systems 38 are not shown, but there can be connections to and from the dense computing systems 38 to and outside the tank 34 and to and from other dense computing systems 38 in the tank 34 or to other dense computing systems 38 arranged in similar tanks 34, adjacent or nearby.

“Two-phase” refers to the dielectric coolant 40 changing thermodynamic phase and removing heat from the dense computing systems 38 in the process. Two-phase cooling removes substantially more heat per unit of volume, compared to techniques using one-phase cooling or forced air/fluid cooling. The dielectric coolant 40 evaporates as the immersed, dense computing systems 38 generate heat as a by-product of their operations. The evaporated coolant bubbles up to the surface of the dielectric coolant 40 in gas form and reaches the condenser 36. The condenser 36 can be hollow and filled with a refrigerant. The condenser 36 can connect to a refrigeration system 44 to remove heat from the condenser 36 and keep its temperature lower than a saturation temperature (evaporation temperature) of the dielectric coolant 40. The refrigeration system 44 can cool a refrigerant inside the condenser 36 to a temperature below the saturation temperature of the dielectric coolant 40. In other embodiments, the condenser 36 maybe a passive condenser, which is cooled by transferring heat to its environment. The condenser 36 can be in any form or shape that can facilitate heat absorption from the evaporated coolant. In some embodiments, the condenser can be a lid enclosing the tank 34 or can be integrated in the lid enclosing the tank 34. The cooler temperature of the condenser condenses the evaporated coolant back to liquid form (causing the liquid to drip back into the dielectric coolant 40). Thus, by-product heat is removed from the dense computing systems 38.

One application of the disclosed two-phase cooling system 32 is that it can allow operation and thermal management of unpackaged or partially-packaged dense computing systems 38. Packaging in dense computing systems 38 can still be challenging, as existing industry tools and infrastructure can be unfit to accommodate packaging of such devices. As a result, the development of dense computing systems 38 has been hampered as they encounter a bottleneck of packaging and effective thermal management. Using the disclosed techniques of two-phase cooling, the dense computing systems 38 can be used unpackaged or partially packaged as the two-phase cooling system 32 offers encapsulation and protection from environmental factors. In other words, the cooling system 32 can function as both packaging and thermal management for the dense computing systems 38. Dense computing systems 38, for example WSI chips, can be made with some or all areas of the system exposed, or without packaging.

At the same time, dense computing systems 38, such as standard WSI systems or WSI systems built according to the embodiments described above, can be desirable computing systems as they promise high performance, high bandwidth computing power and low manufacturing cost per unit of volume of computing power. As described earlier, a technical challenge in their widespread adoption has been effective thermal management, as existing solutions can be inefficient when applied to the computation rate and chip density of dense computing systems 38. The disclosed two-phase thermal management systems (e.g., the two-phase cooling systems 32) can provide efficient cooling of dense computing systems (including WSI, stacked or other highly integrated systems), which has been previously a limiting factor in adoption and success of dense computing systems.

Furthermore, as described earlier, the dense computing systems 38 can be any dense computing systems, including a standard WSI chip, or a partially wafer-scale-integrated chip, or a WSI system built according to the described embodiments above. For example, a partial WSI chip can be manufactured on a silicon wafer, where the portion that is wafer-scale-integrated can be any portion larger than the reticle limit of 858 mm2 when 193 nm immersion steppers are used.

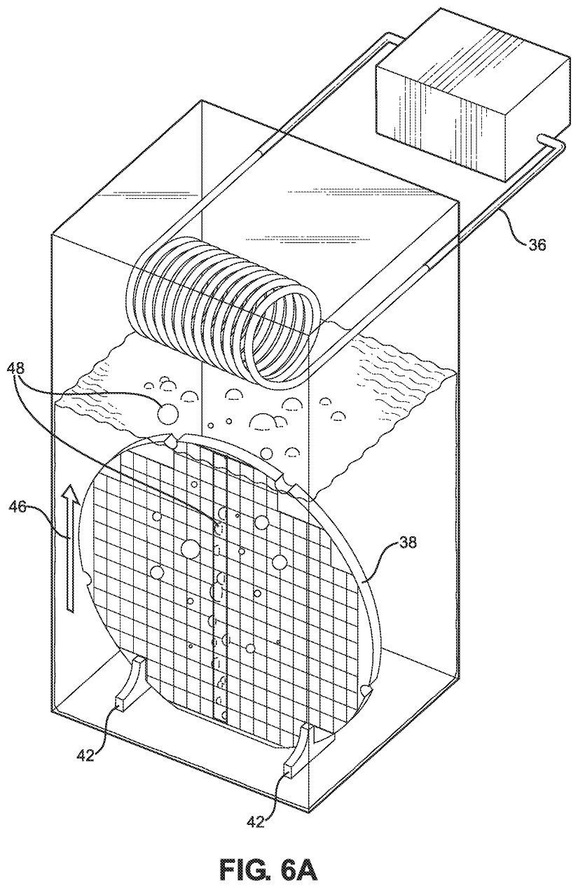

FIG. 5 illustrates an alternative arrangement of the two-phase cooling system 32, where the dense computing systems 38 are arranged horizontally in the tank 34. For illustrations purposes, and as an example, a WSI system built according to the embodiments above is shown for the dense computing systems 38; however, any other dense computing system can be used in addition to or instead of the example shown. The tank 34 may be placed on a resting surface 35. Horizontally arranging dense computing systems 38 in the tank 34 offers the benefit of reduced heat aggregation. By contrast, when computing systems 38 are arranged vertically, the heat absorption capacity of the evaporated coolant droplets rising to the surface of the dielectric coolant 40 gradually decreases as the droplets have to pass over more dies in the vertical direction in order to reach the surface of the dielectric coolant 40. By arranging the dense computing systems 38 in the horizontal direction, the evaporated droplets from any die directly rise to the surface of the dielectric coolant 40, without passing over the surface of any other heat-generating dies. As a result, heat aggregation is reduced and the performance of the two-phase cooling system 32 is improved.

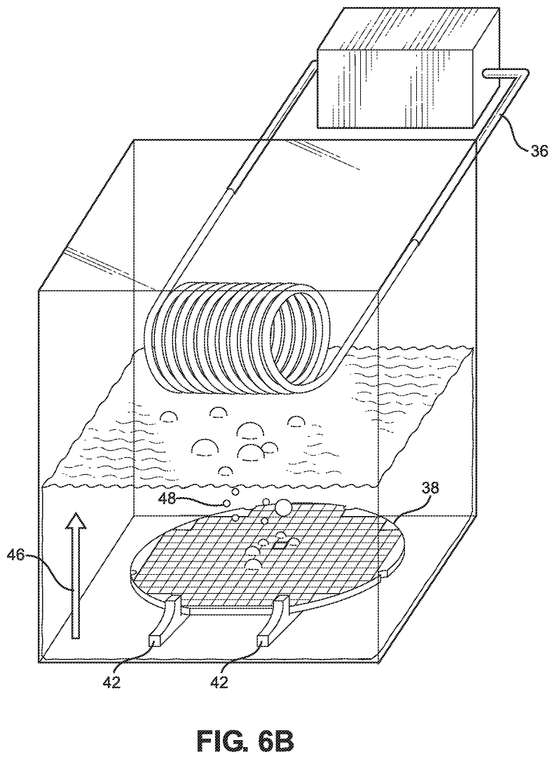

FIG. 6A illustrates a dense computing system 38 placed vertically in the tank 40. As the dielectric coolant 40 is heated by the activity of the dense computing system 38 and the dies therein, evaporated droplets 48 are generated, which travel to the surface of the dielectric coolant 40 in the travel direction 46. In the vertical arrangement of the dense computing system 38, the longer dimension of the dense computing system 38 is parallel to the travel direction 46 of the evaporated droplets 48. As a result, an evaporated droplet 48 travels in the direction of the longer dimension of the dense computing system 38, relative to its shorter dimensions (height and width), passing over heat-generating surface area of more and more dies before it reaches the surface of the dielectric coolant 40 and the condenser 36. Therefore, heat aggregation occurs in the travel direction 46, if the computing system 38 is arranged with its longer dimension (relative to its other dimensions, e.g., width and/or height) in parallel to the travel direction 46.

FIG. 6B illustrates a dense computing system 38 in the horizontal arrangement, where the longer dimension of the dense computing system 38 is perpendicular or nearly perpendicular to the travel direction 46 of the evaporated droplets 48. In the horizontal arrangement of the dense computing system 38, the evaporated droplets 48 do not encounter other heat-generating surface areas on their way up to the surface of the dielectric coolant 40. As a result, heat aggregation is reduced and the performance of the two-phase cooling system 32 is improved.

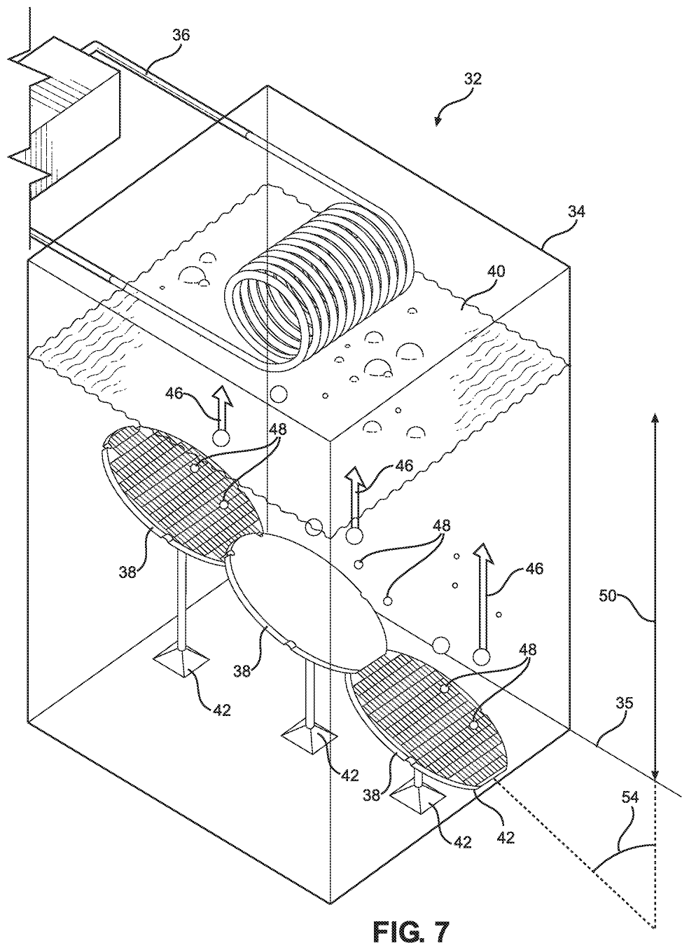

In another embodiment, the dense computing systems 38 need not be arranged horizontally and can be placed in tank 34 with a slight slant, relative to the vertical direction, in order to reduce heat aggregation. The degree of slant can be determined to reduce the horizontal dimension of tank 34, so the two-phase cooling system 32 can occupy less area in the horizontal direction. FIG. 7 illustrates a dense computing system 38 arranged with a slight slant angle 54, relative to the vertical direction 50. The travel direction 46 of the evaporated droplets 48 is in the vertical direction 50 toward the surface of the dielectric coolant 40. The slant angle 54 between the dense computing system 38 and the vertical direction 50 can be in a range such that the evaporated droplets 48 do not contact substantially more heat-generating surface areas after beginning to rise to the surface of the dielectric coolant 40. In some embodiments, the slant angle 54 can be determined empirically. In another embodiment, the slant angle 54 can be chosen from the range of approximately 10 degrees to 90 degrees, relative to the vertical direction 50. The embodiments of FIGS. 4 and 6A illustrate a slant angle 54 of zero degrees. The embodiments of FIGS. 5 and 6B illustrate a slant angle 54 of 90 degrees.

While the described embodiments of systems and methods of cooling computer hardware are illustrated with examples of dense computing systems based on the embodiments of WSI systems as described above, other dense computing systems such as standard WSI systems, three-dimensional (3D) ICs, multilayered ICs and any other computing system can be cooled using the described systems and techniques.

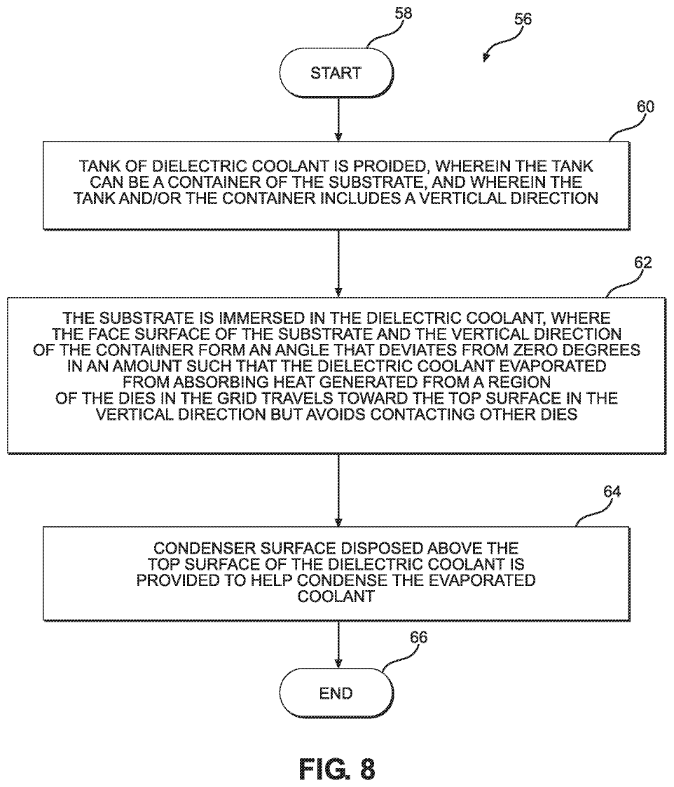

FIG. 8 illustrates a flowchart of a method 56 for cooling a dense computing system. The dense computing system can be built, by forming a plurality of dies arranged in a grid on a face surface of a substrate. The dies can be formed by standard lithographic techniques that print identical copies of dies on a semiconductor substrate (such as crystalline-silicon or other semiconductor substrates or wafers). The dense computing system can also include bridge dies, where two or more dies are electrically coupled with dies in another substrate or with dies cut out (diced) from another substrate and placed on the grid to form electrical connection between the dies of the grid. In another embodiment, multiple substrates each with grids of dies printed on their face surfaces can be arranged in overlapping regions to allow for electrical connections between one or more dies in one substrate to one or more dies in another substrate. The multiple substrates can be in face to face, face to back or back to back orientation, relative to one another, where face surface refers to the surface upon which dies are printed and back surface refers to the opposite surface. The dies can comprise circuits with functionality and/or interconnect and wiring layers. In another embodiment, the dense computing system can be a standard WSI system. For example, those manufactured by Trilogy Systems, now Tata Elxsi Of Bangalore, Karnataka, India (Telephone No. +91 80 2297 9123). In this scenario, a plurality of chips can be fabricated on the substrate (and not necessarily in a grid fashion and not necessarily of identical copies). The plurality of the chips can be interconnected to provide an integrated computer system on the substrate.

The method 56 starts at step 58. At step 60, a tank of dielectric coolant is provided, wherein the tank can be a container of the substrate, and wherein the tank and/or the container includes a vertical direction, such as the vertical direction 50, shown in FIG. 7. Evaporated dielectric coolant travels upward in the coolant toward a top surface of the coolant along the vertical direction. At step 62, the substrate is immersed in the dielectric coolant, where the face surface of the substrate and the vertical direction of the container form an angle that deviates from zero degrees in an amount such that the dielectric coolant evaporated from absorbing heat generated from a region of the dies in the grid travels toward the top surface in the vertical direction but avoids contacting other dies. At step 64 a condenser surface disposed above the top surface of the dielectric coolant is provided to help condense the evaporated coolant. The method ends at step 66.

What is claimed is:

1. A system comprising:
a dense computing system, comprising a substrate and a plurality of dies arranged on the substrate;
a tank of dielectric coolant comprising a container of the substrate, wherein the container comprises a vertical direction in which evaporated dielectric coolant travels upward to reach a top surface of the dielectric coolant, and wherein the substrate is immersed in the dielectric coolant, and wherein the face surface of the substrate and the vertical direction of the container form an angle, and wherein the angle deviates from zero degrees in an amount such that the dielectric coolant evaporated from absorbing heat generated from a region of the plurality of the dies travels toward the top surface in the vertical direction avoiding contact with other dies; and
a condenser surface disposed above the top surface of the dielectric coolant.

2. The system of claim 1, wherein the dense computing system comprises a wafer-scale-integrated computing system or a partially wafer-scale-integrated computing system.

3. The system of claim 1, wherein the angle comprises an angle between approximately 10 to approximately 90 degrees.

4. The system of claim 1, wherein the dielectric coolant comprises a refringent.

5. The system of claim 4, wherein the refrigerant comprises material from hydrofluorocarbon families.

6. The system of claim 1, wherein the face surface comprises functional circuits implementing logic or memory functionality.

7. The system of claim 1, further comprising, one or more bridge dies, electrically coupling two or more dies on the substrate; wherein the bridge die is connected to the two or more plurality of dies via one or more of: through-silicon-vias (TSV), micro-bumps, solder-bumps, C4 bumps, inductive coupling, capacitive coupling, optical coupling, face to face bonding, bonded metal links, and face-to-face vias.

8. The system of claim 1, wherein the dense computing system is unpackaged or partially packaged.

9. The system of claim 7, wherein the bridge die is mechanically connected to the two or more plurality of dies via one or more of direct bonding, anodic bonding, hybrid bonding, glues, epoxies, resins, benzocyclobutene (DVS-BCB) polymers, and thermocompression bonding.

10. The system of claim 1, wherein the dies comprise approximately identical copies of the dies produced from a lithographic technique that prints copies of identical dies on the substrate.

11. The system of claim 1 further comprising a refrigeration unit coupled with the condenser and configured to cool a temperature of a refrigerant inside the condenser to a temperature below a saturation temperature of the dielectric coolant.

12. A method comprising:
forming a dense computing system on a substrate by forming a plurality of dies on a face surface of the substrate;
electrically coupling two or more dies or die regions with one another;
providing a tank of dielectric coolant comprising a container of the substrate, wherein the container comprises a vertical direction in which evaporated dielectric coolant travels upward to reach a top surface of the dielectric coolant;
immersing the substrate in the dielectric coolant, wherein the face surface of the substrate and the vertical direction of the container form an angle, and wherein the angle deviates from zero degrees in an amount such that the dielectric coolant evaporated from absorbing heat generated from a region of the plurality of the dies travels toward the top surface in the vertical direction avoiding contact with other dies; and
providing a condenser surface disposed above the top surface of the dielectric coolant.

13. The method of claim 12, wherein the dense computing system comprises a wafer-scale-integrated computing system or a partially wafer-scale-integrated computing system.

14. The method of claim 12, wherein the angle comprises an angle between approximately 10 to approximately 90 degrees.

15. The method of claim 12, wherein the dielectric coolant comprises a refringent.

16. The method of claim 15, wherein the refrigerant comprises material from hydrofluorocarbon families.

17. The method of claim 12, wherein the face surface comprises implementing logic or memory functionality.

18. The method of claim 12, wherein electrically coupling comprises forming one or more bridge dies, electrically coupling two or more dies on the substrate, wherein the bridge die is connected to the two or more plurality of dies via one or more of: through-silicon-vias (TSV), micro-bumps, solder-bumps, C4 bumps, inductive coupling, capacitive coupling, optical coupling, face to face bonding, bonded metal links, and face-to-face vias.

19. The method of claim 12, wherein the dense computing system is unpackaged or partially packaged.

20. The method of claim 12 further comprising cooling a refrigerant in circulation in the condenser surface.
